(19) United States
(12) Patent Application Publication
(10) Pub. No.: US 2009/0212436 A1
(43) Pub. Date: Aug. 27, 2009

(54) SEMICONDUCTOR STRUCTURE AND METHOD FOR FORMING THE SAME

(75) Inventors: Hsin-Chi Sun, Hsinchu City (TW); Wen-Chung Chen, Changhua County (TW); Chih-Cherng Liao, Hsinchu County (TW); Sung-Min Wei, Hsinchu City (TW)

Correspondence Address: QUINTERO LAW OFFICE, PC, 2210 MAIN STREET, SUITE 200, SANTA MONICA, CA, 90405, US

(73) Assignee: VANGUARD INTERNATIONAL SEMICONDUCTOR CORPORATION, HSINCHU (TW)

(21) Appl. No.: 12/038,747

(22) Filed: Feb. 27, 2008

(51) Int. Cl. H01L 23/48; H01L 21/4763

(52) U.S. Cl. 257/762; 438/622; 257/E21.495; 257/E23.01

(57) ABSTRACT

A semiconductor structure and method for forming the same are provided. The semiconductor structure comprises a semiconductor substrate, a plurality of top metallizations on the semiconductor substrate, a high density plasma layer filling gaps between the top metallizations and having a substantially planar upper surface overlying the top metallizations, and a passivation layer overlying the high density plasma layer. A metal bump can be formed overlying the top metallizations through the passivation layer and HDPCVD layer for subsequent bonding.

### BACKGROUND OF THE INVENTION

1. Field of the Invention

The invention relates to a semiconductor structure, and more particularly to a semiconductor structure having an extra thin passivation layer and method for forming the same.

2. Description of the Related Art

The packaging process for an integrated circuit (IC) is an important step in the manufacturing of ICs, which affect total cost, performance, and reliability of semiconductor devices. Meanwhile, requirement for miniaturization of semiconductor devices have increased along with requirement for pin count.

Given the trend for smaller, lighter, and thinner electronic products, flip chip technology has become a very popular semiconductor packaging technique. For flip chip technology, metal bumps are utilized to connect ICs electrically and mechanically to packaged substrates, instead of conventional wire bonding. Thus, reducing packaging area and increasing device density for electronic products as well as performance.

Metal bumps are formed on top metallizations of a semiconductor substrate, which are surrounded by dielectric layers and passivation layers overlying the top metallizations. In order to further increase density and quality of semiconductor packaging, dielectric layers and passivation layers between metal bumps and top metallizations have become important areas for research.

### BRIEF SUMMARY OF INVENTION

The present invention provides a semiconductor structure, comprising a semiconductor substrate, a plurality of top metallizations on the semiconductor substrate, a high density plasma layer filling gaps between the top metallizations and having a substantially planar upper surface overlying the top metallizations, and a passivation layer overlying the high density plasma layer.

The present invention further provides a method for forming a semiconductor structure, comprising providing a semiconductor substrate, forming a plurality of top metallizations on the semiconductor substrate, forming a high density plasma layer filling gaps between the top metallizations and having a protruding surface, planarizing the high density plasma layer to provide a substantially planar upper surface, and forming a passivation layer overlying the planar high density plasma layer.

### BRIEF DESCRIPTION OF DRAWINGS

The invention can be more fully understood by reading the subsequent detailed description and examples with references made to the accompanying drawings, wherein:

FIGS. 1A-1B are cross-sectional views showing the steps for fabricating a semiconductor structure known to the inventors;

FIGS. 2A-2F are cross-sectional views showing the steps for fabricating a semiconductor structure according to one embodiment of the present invention.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

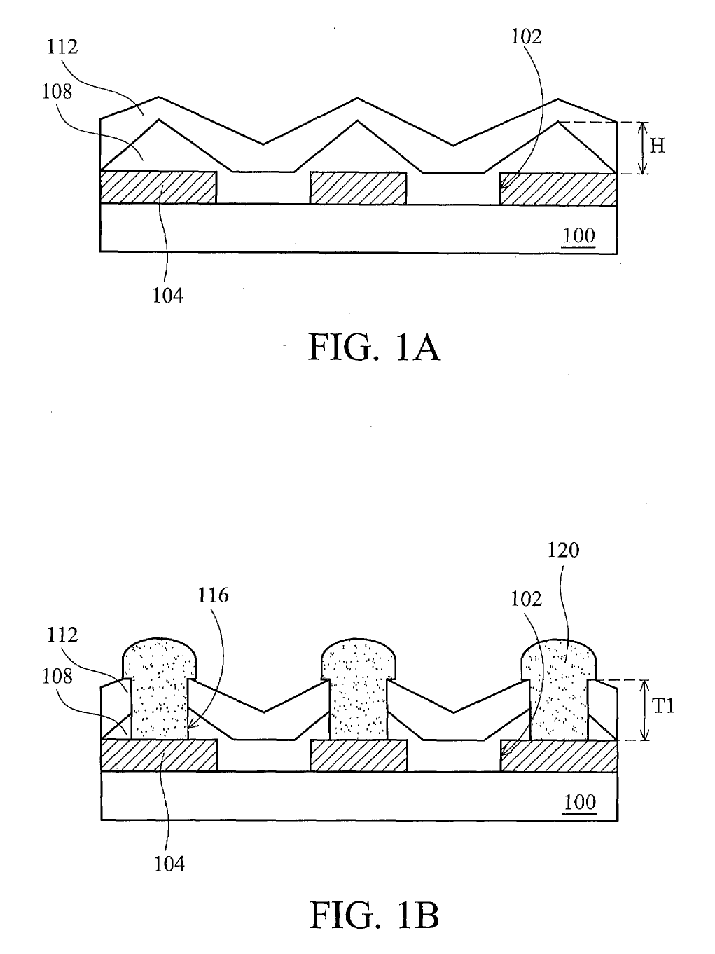

FIGS. 1A-1B demonstrate a method known to the inventors for forming a semiconductor structure. The method is not prior art for the purpose of determining the patentability of the present invention. The method merely shows a problem discovered by the inventors.

As shown in FIG. 1A, a plurality of top metallizations 104 are formed overlying a substrate 100. Next, a silicon oxide layer 108 is formed overlying the top metallizations 104 and filling the gaps 102 between the top metallizations 104. In order to make the silicon oxide layer 108 substantially fill the gaps 102, a high density plasma deposition technique is carried out to deposit a silicon oxide layer 108. Then, a silicon nitride layer 112 with a thickness between about 5000 Å and 7000 Å is formed overlying the silicon oxide layer 108. An opening 116 is then formed in the silicon oxide layer 108 and the silicon nitride layer 112 to expose the top metallization 104, as shown in FIG. 1B. Finally, a metal bump 120, such as a gold bump, which may be used for flip chip packaging, is formed in the opening 116 overlying the exposed top metallization 104.

However, requirement for a thick silicon nitride layer may introduce too much stress to the substrate 100 and cause damage to devices, since silicon nitride is a harder material. Specifically, referring to FIG. 1A, the silicon oxide layer 108 formed by a high density plasma deposition technique may result in a protruding part (or a raised part) overlying the top metallizations 104, which may be caused by the inherent characteristics of the high density plasma deposition technique. The height H of the protruding part (or the raised part) is about 7000 Å, thus the following deposited silicon nitride layer 112 is required to be formed with a higher thickness to cover the rough underlying silicon oxide layer 108. The thickness of the silicon nitride layer 112 is usually as thick as about 7000 Å. Otherwise, a thinner silicon nitride layer may have too rough of a surface to provide uniform protection to the underlying ICs.

In addition, as shown in FIG. 1B, when the metal bump 120 is formed in the opening 116 above the top metallization 104, the metal bump 120 is required to be filled into the opening 116 with a depth T1, wherein the depth T1 is about 14000 Å. Because the total thickness of the silicon oxide layer 108 and silicon nitride layer 112 is very thick, the amount of the material required to fill the opening 116 for forming the metal bump 120, results in higher manufacturing costs.

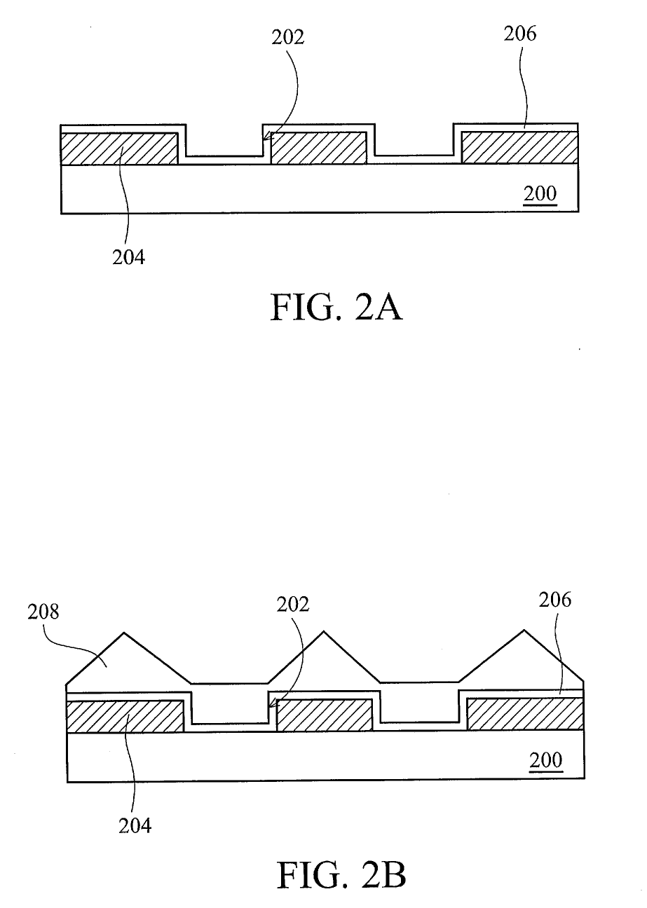

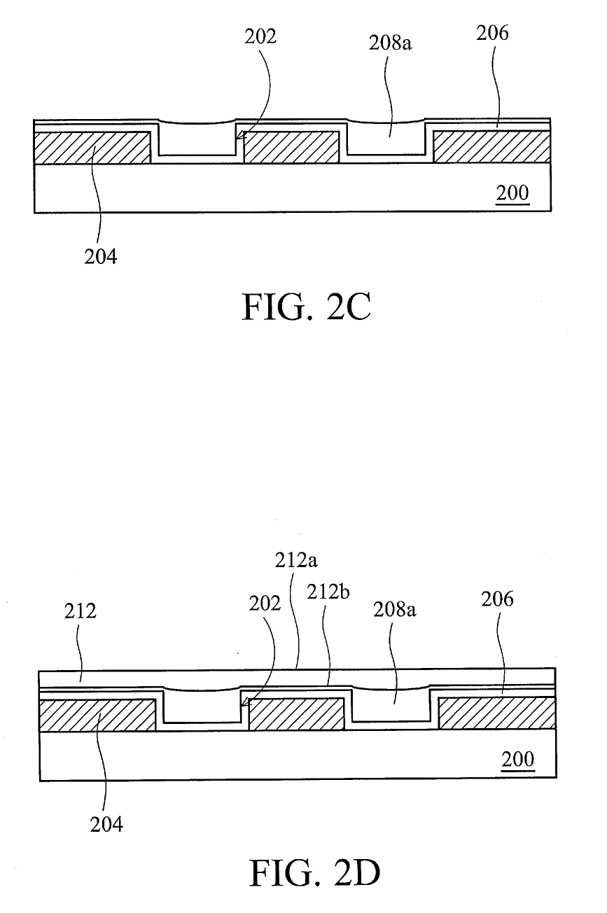

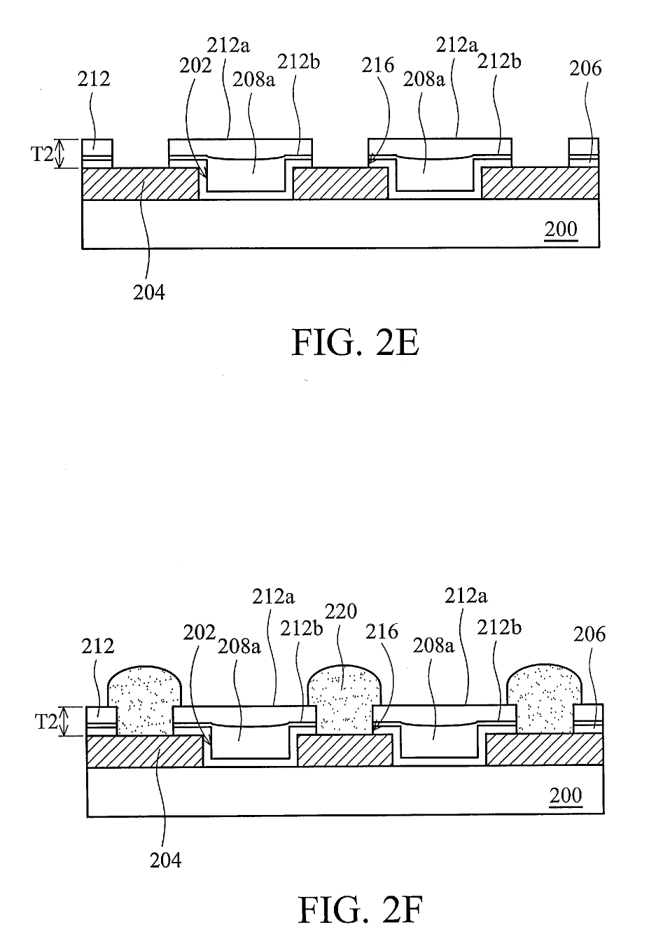

To solve the problems mentioned above, the present invention provides a semiconductor structure with an extra thin passivation layer, which may improve the flatness of the passivation layer and prevent crack problems of the passivation layer. The amount of material used to form the passivation layers and metal bumps may be effectively reduced. In the following, the manufacturing steps of one embodiment of the present invention will be described in detail with respect to FIGS. 2A-2F.

As shown in FIG. 2A, a semiconductor substrate 200 is provided. The semiconductor substrate 200, such as a silicon wafer, may have many kinds of semiconductor devices formed thereon, such as transistors, resistors, or logic devices, and so on. To simplify the figure, the devices formed in the semiconductor substrate 200 are not shown. A plurality of top metallizations 204 are formed on the semiconductor substrate 200. A plurality of gaps 202 are also formed between the top metallizations 204. The material of the top metallization 204 may comprise common metals, such as aluminum, copper, silver, gold, or combinations thereof. A top metal layer may be formed on the semiconductor substrate 200 by vapor deposition methods or electrical plating. Then, the top metal layer may be formed into a plurality of separate top metallizations 204 by a photolithography and etching process, thus leaving a plurality of gaps 202 between the top metallizations 204. Next, a stop layer 206 is deposited overlying the top metallization 204 first, before filling an oxide layer into the gaps 202 between the top metallizations 204. The stop layer 206 will serve as a stop layer during a following planarization process of an oxide layer. In the embodiment, the stop layer 206 is deposited conformally overlying the upper surface and the sidewalls of the top metallizations 204 and the upper surface of the semiconductor substrate 200. The material of the stop layer 206 may be silicon oxynitride and the thickness of the stop layer 206 may be between about 400 Å and 1500 Å.

FIG. 2B shows the formation of a high density plasma layer 208. The material of the high density plasma layer 208 is usually oxide, such as silicon oxide, which has excellent gap filling ability. After the high density plasma layer 208 is substantially filled into the gaps 202, a protruding part (or a raised part) is formed above the top metallization 204, which is caused by the inherent characteristics of the high density plasma deposition technique.

As shown in FIG. 2C, a planarization process is performed to the high density plasma layer 208 with a protruding part to make the high density plasma layer 208 a high density plasma layer 208a with a substantially planar upper surface. In an embodiment, the planarization process may be a chemical mechanical polishing process. The chemical mechanical polishing process may proceed until the stop layer 206 is exposed using an end point detection mode. The chemical mechanical polishing process may also proceed using a time setting mode to stop the planarization process before the stop layer 206 is exposed. As shown in FIG. 2C, although there is still some residual high density plasma layer 208a overlying the top metallization 204, one skilled in the art should understand that the high density plasma layer 208a overlying the top metallization 204 may also be completely removed and only the high density plasma layer 208a between the top metallizations 204 would remain.

FIG. 2D shows the formation of a passivation layer 212. The material of the passivation layer 212 may be, for example, silicon nitride. In an embodiment, because the high density plasma layer 208a has a substantially planar upper surface, the passivation layer 212 can be deposited above the planar upper surface 212b, such that it is not necessary to form a thick passivation layer to cover the high density plasma layer. Additionally, the passivation layer 212 may have a substantially planar upper surface. The thickness of the passivation layer 212 may be between about 5000 Å and 6500 Å. In an embodiment, the total thickness between the upper surface of the top metallization 204 and the upper surface 212a of the passivation layer 212 are, for example, less than about 7000 Å. The amount of material used to form the passivation layer may be decreased, thus forming a passivation layer with good quality and less stress.

FIGS. 2E and 2F show a metal bump forming process. First, an opening 216 is formed in the passivation layer 212 and the stop layer 206 overlying the top metallization 204 using a photolithography and an etching process, as shown in FIG. 2E. The thickness T2 of the opening 206 equals to the thickness of the passivation layer 212 and the stop layer 206, which may be about 7000 Å. The opening 216 penetrates through the passivation layer 212, the high density plasma layer 208a, and the stop layer 206 exposing at least a part of the top metallization 204. A metal bump 220 is then deposited into the opening 216 by, for example, by a vapor deposition method or electrical plating process, as shown in FIG. 2F. The metal bump 220 may be a little higher than the upper surface 212a of the passivation layer 212. The thickness of the metal bump 220 may be less than about 8000 Å. The material of the metal bump 220 may comprise gold, silver, copper, tin, lead, or combinations thereof. [0020] In addition, before forming the metal bump 220, an under-bump metallization layer may be formed first on the surface of the opening 216 (not shown in the figure) to improve the bonding between the metal bump 220 and the top metallization 204. The under-bump metallization layer may also protect the top metallization 204 and serve as a wetting layer during the following reflow process. The material of the under-bump metallization layer may comprise titanium, tungsten, gold, or combinations thereof.

As shown in FIG. 2F, the thickness of the metal bump 220 filling into the passivation layer 212, the high density plasma layer 208a, and the stop layer 206 is very small, such as a thickness of less than about 7000 Å. Thus, the amount of material used to form the metal bump 220 is decreased. Especially, when gold is chosen to form the metal bump 220, the cost of fabricating the semiconductor structure according to an embodiment of the present invention may be significantly reduced. Furthermore, the passivation layer 212 with higher stress, such as a passivation layer made of silicon nitride, may have a thinner thickness and a substantially planar upper surface, which makes it possible to introduce less stress damage to the semiconductor substrate and increase product yield of the flip chip packages. One of the advantageous features of the embodiment of the present invention is that the semiconductor structure has an extra thin passivation layer, which may not only save the amount of material used, but also reduce the space needed for packaging. Since the thickness of the passivation layer is reduced, the stress damage may also be reduced. The density and reliability of the devices may also be improved along with performance.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a semiconductor substrate;
a plurality of top metallizations on the semiconductor substrate;
a high density plasma layer filling gaps between the top metallizations and having a substantially planar upper surface overlying the top metallizations; and
a passivation layer overlying the high density plasma layer.

2. The semiconductor structure as claimed in claim 1, further comprising a stop layer conformally overlying the top metallizations and the semiconductor substrate.

3. The semiconductor structure as claimed in claim 2, wherein the stop layer comprises silicon oxynitride.

4. The semiconductor structure as claimed in claim 2, wherein the stop layer has a thickness of less than about 1500 Å.

5. The semiconductor structure as claimed in claim 1, wherein the passivation layer has a thickness of less about 5000 Å.

6. The semiconductor structure as claimed in claim 1, wherein a total thickness between the upper surface of the top metallizations and the upper surface of the passivation layer is less than about 7000 Å.

7. The semiconductor structure as claimed in claim 1, wherein the passivation layer has a substantially planar upper surface.

8. The semiconductor structure as claimed in claim 1, further comprising a metal bump overlying the top metallizations through the passivation layer.

9. The semiconductor structure as claimed in claim 8, wherein the metal bump comprises gold, silver, copper, tin, lead, or combinations thereof.

10. The semiconductor structure as claimed in claim 1, wherein the high density plasma layer comprises an oxide layer.

11. The semiconductor structure as claimed in claim 1, wherein the passivation layer comprises silicon nitride.

12. A method for forming a semiconductor structure, comprising:
providing a semiconductor substrate;
forming a plurality of top metallizations on the semiconductor substrate;
forming a high density plasma layer filling gaps between the top metallizations and having a protruding surface;
planarizing the high density plasma layer to provide a substantially planar upper surface; and
forming a passivation layer overlying the planar high density plasma layer.

13. The method for forming a semiconductor structure as claimed in claim 12, wherein the planarization is carried out by a chemical mechanical polishing process.

14. The method for forming a semiconductor structure as claimed in claim 13, further comprising forming a stop layer conformally overlying the top metallizations and the semiconductor substrate.

15. The method for forming a semiconductor structure as claimed in claim 14, wherein the stop layer has a thickness of less than about 1500 Å.

16. The method for forming a semiconductor structure as claimed in claim 12, wherein the passivation layer has a thickness of less than about 5000 Å.

17. The method for manufacturing a semiconductor structure as claimed in claim 12, wherein a total thickness between the upper surface of the top metallizations and the upper surface of the passivation layer is less than about 7000 Å.

18. The method for manufacturing a semiconductor structure as claimed in claim 12, wherein the passivation layer has a substantially planar upper surface.

19. The method for manufacturing a semiconductor structure as claimed in claim 12, further comprising forming an opening in the passivation layer to expose the top metallization and forming a metal bump in the opening overlying the top metallization.
